(19) United States
(12) Patent Application Publication
(10) Pub. No.: US 2009/0303669 A1
(43) Pub. Date: Dec. 10, 2009

(54) HOUSING OF ELECTRONIC DEVICE

(75) Inventors: CHE-YUAN HSU, Shindian (TW); CHENG-WEN SU, Shindian (TW); GANG HUANG, Shenzhen City (CN); YAN-MIN WANG, Shenzhen City (CN); QIANG WANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/262,190

(22) Filed: Oct. 31, 2008

(30) Foreign Application Priority Data
Jun. 4, 2008 (CN) 200810301976.7

(51) Int. Cl. H05K 7/00

(52) U.S. Cl. 361/679.01

(57) ABSTRACT

A housing (10) for use in a portable electronic device 100, includes a latching member (14) and a film layer (122). The film layer (122) includes a displaying section (1222) and a connecting section (1224). The connecting section (1224) extends upwardly from the displaying section (1222). The displaying section (1222) has a window (1228) arranged thereon. The connecting section (1224) is integrally molded with the latching member (14).

### BACKGROUND

1. Field of the Invention

The present invention relates to housings, particularly to housings used in electronic devices.

2. Description of Related Art

With the development of wireless communication and information processing technology, portable electronic devices (such as mobile telephones and electronic notebooks) are now in widespread use. External appearance of the housing of the portable electronic device has become a key factor for attracting consumers.

The external appearance of the housing can usually be made by In-Mold Labeling (IML) on the housing. A decorative film with predetermine patterns is disposed and adhered on the housing within a die. However, the decorative film has a deformation coefficient different from the housing. Thus, stress may occur between the decorative film and the housing while injecting melted plastic to mold the housing, which may cause a birefringence between the decorative film and the housing. Thus, the transparent quality of the housing may be degraded.

Therefore, there is room for improvement within the art.

### BRIEF DESCRIPTION OF THE DRAWINGS

Many aspects of the exemplary housing of an electronic device can be better understood with reference to the following drawings. These drawings are not necessarily drawn to scale, the emphasis instead being placed upon clearly illustrating the principles of the present methods. Moreover, in the drawings like reference numerals designate corresponding parts throughout the several views. Wherever possible, the same reference numbers are used throughout the drawings to refer to the same or like elements of an embodiment.

FIG. 1 is a schematic and assembled view of a housing in accordance with an exemplary embodiment.

FIG. 2 is a schematic and an exploded view of the housing shown in FIG. 1.

FIG. 3 is a schematic and cross sectional view of the housing shown in FIG. 1.

### DETAILED DESCRIPTION OF THE EXEMPLARY EMBODIMENTS

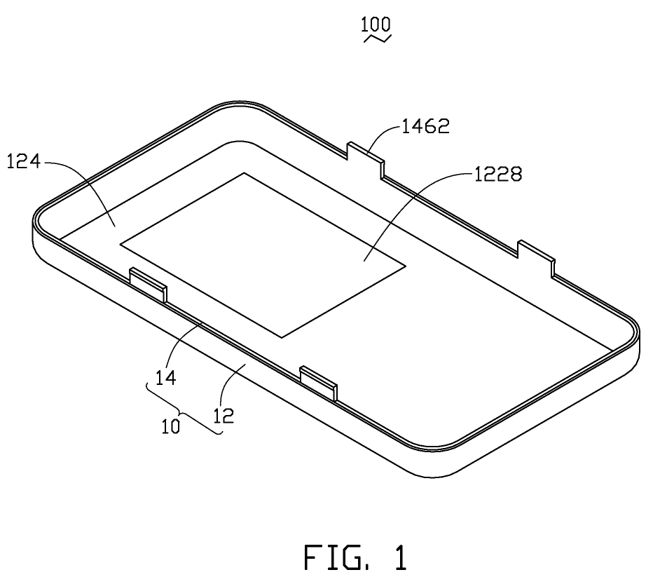

FIG. 1 shows a portion of a portable electronic device 100, such as mobile phone. The portable electronic device 100 includes a housing 10. The housing 10 includes a base 12 and a latching member 14 integrally formed (e.g., molded) with the base 12.

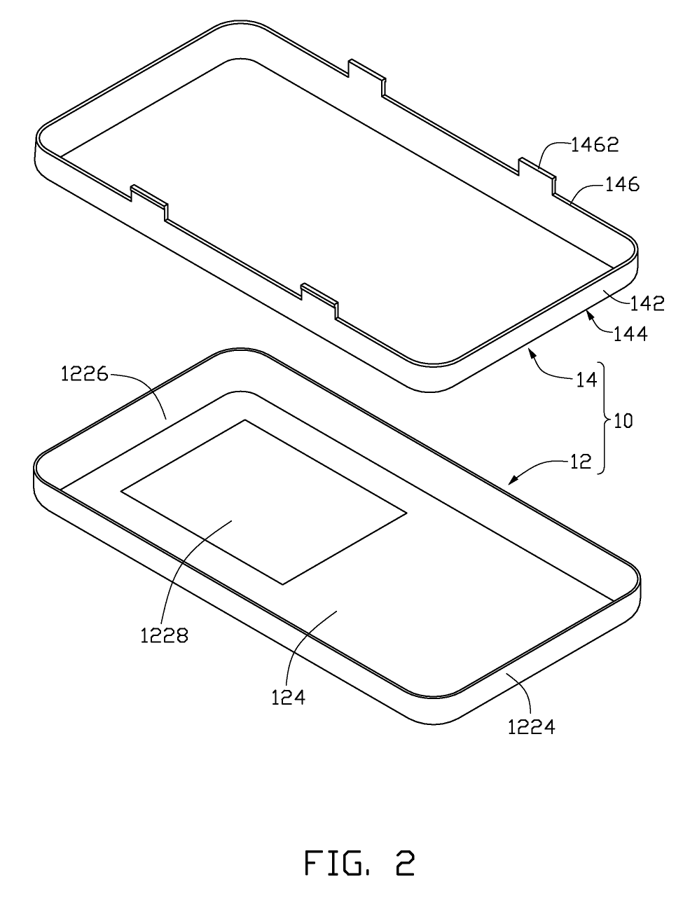

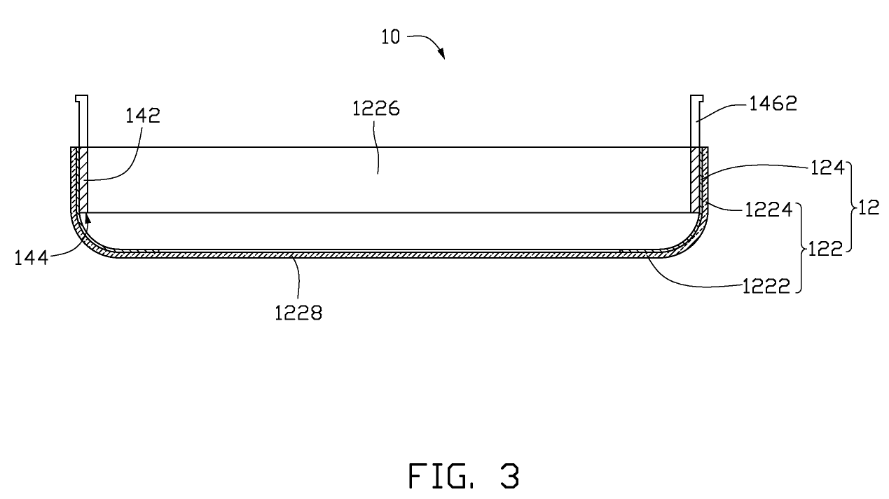

Referring to FIGS. 2 and 3, the base 12 includes a film layer 122 and a shading layer 124 formed (e.g., painted) on the film layer 122. The film layer 122 includes a displaying section 1222 and a connecting section 1224 extending upwardly from the edges of the displaying section 1222. The displaying section 1222 and the connecting section 1224 cooperatively define a cavity 1226 for accommodating electronic components of the portable electronic device 100. The displaying section 1222 has a window 1228 defined at a central portion thereof. The shading layer 124 is attached on an interior surface of the film layer 122 and surrounds the window 1228.

The film layer 122 may be made of transparent plastic selected from a group including polymethyl methacrylate and polystyrene. The film layer 122 has a thickness ranging from about 0.5 millimeter to about 1.5 millimeters. The shading layer 124 may be ink film, painted film or metallic film.

Referring to FIGS. 2 and 3, the latching member 14 includes a generally rectangular frame 142 configured to be secured to the connecting section 1224, a bottom end 144 configured to face the displaying section 1222, and an upper end 146 opposite to the bottom end 144. The frame 142 connects the bottom end 144 and the upper end 146. The frame 142 can be integrally interlocked (e.g., molded) to the interior surface of the connecting section 1224. It is to be understood that the frame 142 and the connecting section 1224 may be integrally adhered or hot melted with each other. The upper end 146 has a plurality of latches 1462 protruding outwardly. The latches 1462 are used for latching with other portions (not shown) of the portable electronic device 100.

The latching member 14 may be made of a material selected from a group including polyvinyl chloride (PVC), polycarbonate, polystyrene, and any other thermoplastic resins.

The window 1228 has no thermoplastic plastic injected thereon. Accordingly, no stresses occurr on the window 1228. The window 1228 can prevent birefringence to improve the transparent quality of the housing 10.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing for a portable electronic device, comprising:
a latching member; and
a film layer including a displaying section and a connecting section, the connecting section extending upwardly from the displaying section, the displaying section having a window defined thereon, the connecting section being integrally formed with the latching member.

2. The housing as claimed in claim 1, wherein the connecting section has an inner surface, the latching member attached to the inner surface.

3. The housing as claimed in claim 1, wherein the housing further includes a shading layer, the shading layer formed on an inner surface of the film layer surrounding the window.

4. The housing as claimed in claim 1, wherein the shading layer is ink film, paint film or metal film.

5. The housing as claimed in claim 1, wherein the film layer is made of transparent plastic.

6. The housing as claimed in claim 5, wherein the transparent plastic is polymethyl methacrylate and polystyrene

7. The housing as claimed in claim 1, wherein the latching member includes a frame, a bottom end, and an upper end located opposite to the bottom end, the frame connects the bottom end and the upper end.

8. The housing as claimed in claim 7, wherein the bottom end faces the displaying section and the upper end has a plurality of latches.

9. The housing as claimed in claim 1, wherein the film layer has a thickness ranged from about 0.5 millimeter to about 1.5 millimeters.

10. The housing as claimed in claim 1, wherein the connecting section is integrally molded with the latching member

11. A portable electronic device, comprising:
a housing, comprising:
a latching member; and
a film layer including a displaying section and a connecting section, the connecting section extending upwardly from the displaying section, the displaying section having a window defined thereon, the connecting section being integrally formed with the latching member.

12. The housing as claimed in claim 11, wherein the connecting section has an inner surface, the latching member attached to the inner surface.

13. The housing as claimed in claim 11, wherein the housing further includes a shading layer, the shading layer formed on an inner surface of the film layer surrounding the window.

14. The housing as claimed in claim 11, wherein the shading layer is ink film, paint film or metal film.

15. The housing as claimed in claim 1, wherein the film layer is made of transparent plastic.

16. The housing as claimed in claim 15, wherein the transparent plastic is polymethyl methacrylate and polystyrene

17. The housing as claimed in claim 11, wherein the latching member includes a frame, a bottom end, and a upper end located opposite to the bottom end, the frame connects the bottom end and the upper end.

18. The housing as claimed in claim 17, wherein the bottom end faces the displaying section and the upper end has a plurality of latches.

19. The housing as claimed in claim 11, wherein the film layer has a thickness ranged from about 0.5 millimeter to about 1.5 millimeters.

20. The housing as claimed in claim 11, wherein the connecting section is integrally molded with the latching member
